(19) United States
(12) Patent Application Publication
(10) Pub. No.: US 2005/0012179 A1
(43) Pub. Date: Jan. 20, 2005

(54) Semiconductor device

(75) Inventor: Hiroshi Saito, Ota-shi (JP)

Correspondence Address: SOCAL IP LAW GROUP, 310 N. WESTLAKE BLVD. STE 120, WESTLAKE VILLAGE, CA, 91362, US

(73) Assignee: Sanyo Electric Co, Ltd., Osaka (JP)

(21) Appl. No.: 10/892,672

(22) Filed: Jul. 15, 2004

(30) Foreign Application Priority Data
Jul. 15, 2003 (JP) 2003-197068

(51) Int. Cl. H01L 29/00

(52) U.S. Cl. 257/532

(57) ABSTRACT

There is disclosed a semiconductor device comprising a capacitive element group that has a plurality of unit capacitive elements. The unit capacitive element has a capacitance value that is set so as to reduce an error between a target capacitance value of the capacitive element group and a combined capacitance value of the plurality of unit capacitive elements making up the capacitive element group. Furthermore, a plurality of the capacitive element groups can be formed in the semiconductor device.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by any one of the patent disclosure as it appears in the Patent and Trademark Office patent files or records, but otherwise reserves all copyright and trade dress rights whatsoever.

### RELATED APPLICATION INFORMATION

The present application claims priority upon Japanese Patent Application No. 2003-197068 filed on Jul. 15, 2003, which is herein incorporated by reference.

### BACKGROUND OF THE INVENTION

1. Field of the Invention

The present invention relates to a semiconductor device.

2. Description of the Related Art

A semiconductor device is known that incorporates a plurality of capacitive elements. Such a semiconductor device is configured, for example, with bipolar integrated circuits. See, for example, Japanese Patent Application Laid-open Publication No. 1999-312784. FIG. 9 shows an example of a cross-sectional structure of a unit capacitive element used in the bipolar integrated circuit. As shown in FIG. 9, a unit capacitive element Cy comprises a P-type semiconductor substrate 1, a P-type isolation region 2, an island region 3 made up of an N-type layer surrounded by the isolation region 2, an N-type bottom electrode region 4 formed on the surface of the island region, an oxide film 5, a dielectric thin film 6 such as silicon nitride film, an aluminum top electrode 7 and a lead-out electrode 8 of a bottom electrode. Its capacitance value is roughly determined by the area of the dielectric thin film 6 in contact with the surface of the bottom electrode 4. This area is equal to the area of an opening portion 5a cleared of the oxide film 5 covering the bottom electrode 4.

As shown in a plan view of FIG. 10, capacitive element groups Ca and Cb are configured through parallel connection of the unit capacitive elements Cy. In the case of a capacitance ratio of 5:15 (1:3), five of the unit capacitive elements Cy are arranged side by side to form the capacitive element Ca. On the other hand, 15 of the unit capacitive elements Cy are arranged side by side to form the capacitive element Cb. The unit capacitive elements Cy of each of the capacitive element groups Ca and Cb are connected to a respective common electrode 12, 13 with connection electrodes 11.

The unit capacitive elements Cy making up each of the capacitive element groups Ca and Cb are connected in parallel each by the electrode wire 11 connected to the top electrode 7. In the case of a three-layer aluminum wiring, the electrode wire is formed by the third wire layer, i.e., the wire layer located at the topmost. The bottom electrode 4 of each of the unit capacitive elements Cy is connected to ground potential GND.

Configuring the above capacitive element groups Ca and Cb presents problems in design and layout pattern of the unit capacitive elements Cy. That is, it is necessary, out of demands for downsizing and higher accuracy of semiconductor devices, to use the smallest possible unit capacitive elements for capacitive element groups for highly accurate capacitance value and capacitance ratio.

In general, however, the smaller the capacitance value of the unit capacitive element Cy for smaller area, the poorer the accuracy of the overall capacitance value and capacitance ratio. For this reason, it is necessary to reduce the area without degrading their accuracy.

However, the conventional design of the unit capacitive element Cy and the aforementioned layout method shown in FIG. 10 have been unfit for high accuracy of capacitance value and ratio and for downsizing. That is, if the unit capacitive elements Cy is simply reduced in size for downsizing, the capacitance value of the entire capacitive element group falls outside the desired range of values, resulting in larger error.

It is also necessary to first route the connection electrode 11 for connection with the common electrode 12 or 13 for each of the unit capacitive elements Cy in the capacitive element group Ca or Cb, thus inhibiting downsizing. This aspect is also true when a connection electrode 11 is routed for connecting a common electrode to the lead-out electrode 8.

Further, the plurality of capacitive element groups Ca and Cb are arranged on the same integrated circuit. This results in the connection electrodes 11 and the common electrode 12, 13 being arranged for each of the capacitive element groups, thus inhibiting downsizing.

### SUMMARY OF THE INVENTION

According to a first aspect of the present invention there is provided a semiconductor device comprising a capacitive element group that has a plurality of unit capacitive elements, wherein the unit capacitive element has a capacitance value that is set so as to reduce an error between a target capacitance value of the capacitive element group and a combined capacitance value of the plurality of unit capacitive elements making up the capacitive element group.

It is therefore possible to set the unit capacitive elements capable of minimizing the error with respect to the target capacitance value to the extent possible, thus allowing the group of highly accurate capacitive elements to be obtained.

The capacitive element groups can also be formed in plurality.

Further, even if there are provided the plurality of capacitive element groups, it is possible to set the unit capacitive elements capable of minimizing the error with the target capacitance value to the extent possible, thus allowing the groups of highly accurate capacitive elements to be obtained.

Still further, the plurality of capacitive element groups can use in common the unit capacitive element having the capacitance value which is set so as to make the error smaller. Therefore, selection of the common unit capacitive element for all the capacitive element groups facilitates patterning, thus reducing to the extent possible variations in capacitance value due to variations in manufacture. This in turn facilitates manufacturing processes, thus providing improved accuracy of capacitance ratio.

Some of the capacitive element groups can each include a unit capacitive element having a capacitance value specific thereto which is set so as to make the error smaller, and a unit capacitive element making up the capacitive element groups other than the some of the capacitive element groups can be equivalent to any one of the unit capacitive elements making up the some of the capacitive element groups.

It is therefore possible to reduce variations in capacitance value due to variations in manufacture, as compared with setting the capacitance value of the unit capacitive element individually for each of the capacitive element groups.

Further, at least one lead-out electrode for bottom electrodes of the unit capacitive elements of the capacitive element group can be disposed along a circumference going around top electrodes as a whole of the capacitive element group.

It is therefore unnecessary to route the lead-out electrode for each of the unit capacitive elements, allowing downsizing of the semiconductor device through area reduction of the capacitive element group and providing improved patterning accuracy as a result of easier patterning. This in turn leads to improved accuracy in capacitance ratio. The lead-out electrode is disposed so as to surround the top electrodes as a whole of the capacitive element group. This ensures further reduction of the capacitive element group in area. The lead-out electrode is disposed so as to surround the top electrodes as a whole, facilitating connection of the lead-out electrode with external and other circuitry. Further, if there are provided a plurality of capacitive element groups, it is unnecessary to dispose the lead-out electrode for each of the capacitive element groups, allowing reduction in area of the plurality of capacitive element groups as a whole. This leads to downsizing of the semiconductor device provided with the plurality of capacitive element groups.

If there is a vacant region free of the unit capacitive elements between the top electrodes as a whole of the capacitive element group and the lead-out electrode, dummy elements must be disposed in the vacant region. This prevents generation of steps as a result of no elements existing in the vacant region, thus facilitating patterning and providing improved patterning accuracy. This in turn leads to improved accuracy of capacitance ratio.

Still further, if the number of unit capacitive elements differs between the capacitive element groups, a capacitive element group having a larger number of unit capacitive elements can be disposed so as to surround a capacitive element group having a smaller number of unit capacitive elements. This eliminates useless space to the extent possible, thus allowing downsizing as a whole.

One lead-out electrode can be formed by integrating the at least one lead-out electrode of the unit capacitive elements. It is therefore unnecessary to route the lead-out electrode for each of the unit capacitive elements, allowing downsizing of the semiconductor device through area reduction of the capacitive element group and providing improved patterning accuracy as a result of easier patterning. This in turn leads to improved accuracy of capacitance ratio.

Further, the unit capacitive elements can be arranged in grid form, with the top electrodes of the unit capacitive elements adjacent to each other joined together in the capacitive element group. This eliminates the need to form a wiring pattern for drawing out the top electrode outwards for each of the unit capacitive elements, making it possible to mount the unit capacitive elements at high density and thereby ensuring further reduction of the capacitive element groups in area. This leads to further downsizing of the semiconductor device. Arrangement of the unit capacitive elements in grid form provides improved patterning accuracy, thus ensuring improved accuracy of capacitance ratio.

### DESCRIPTION OF THE DRAWINGS

The above and other objects, aspects, features and advantages of the present invention will become more apparent from the following detailed description when taken in conjunction with the accompanying drawings, in which:

FIG. 1 is a plan view of a semiconductor device according to an embodiment of the present invention;

FIG. 2 is a plan view of a semiconductor device according to another embodiment of the present invention;

FIG. 3 is a table showing data such as capacitance values and errors of unit capacitive elements Cu for implementing capacitive element groups C1 and C2 according to the embodiment of the present invention;

FIG. 4 is a table showing data such as capacitance values and errors of unit capacitive elements Cu for implementing capacitive element groups C5 and C6 according to the another embodiment of the present invention;

FIG. 5 is a table showing data such as capacitance values and errors of unit capacitive elements Cu for implementing capacitive element groups C3 and C4 according to the another embodiment of the present invention;

FIGS. 6A and 6B are circuit diagrams showing examples of configuration of a voltage dividing circuit using the semiconductor device of FIG. 1;

FIGS. 7A to 7C are circuit diagrams showing examples of configuration of a voltage dividing circuit using the semiconductor device of FIG. 2;

FIG. 8 is a circuit diagram showing a comparator to which the voltage dividing circuits of FIGS. 6A and 6B and FIGS. 7A to 7C are connected;

FIG. 9 is a view showing an example of a cross-sectional structure of a unit capacitive element that may be shared by the conventional art and the present invention;

FIG. 10 is a plan view of a layout pattern of the conventional art unit capacitive elements;

FIG. 11 is a view showing an example of a cross-sectional structure of a unit capacitive element according to an embodiment of the present invention; and

FIG. 12 is a view of the cross-sectional structure of the semiconductor device of FIG. 1.

### DETAILED DESCRIPTION OF THE INVENTION

<Layout of Unit Capacitive Elements>

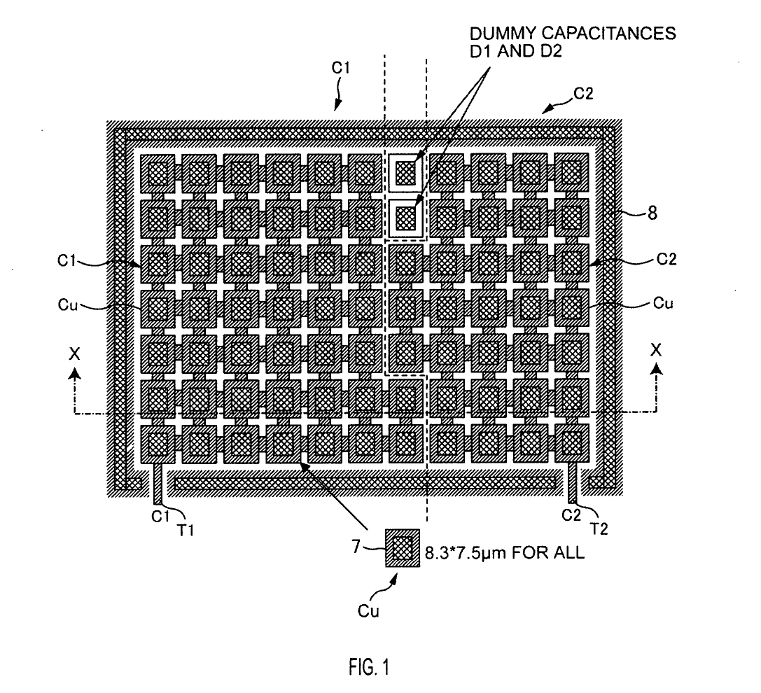

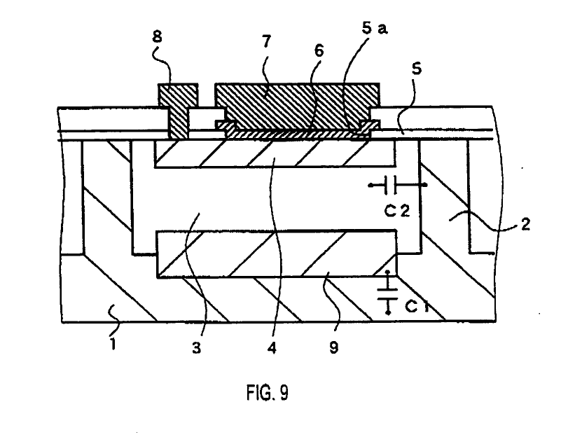

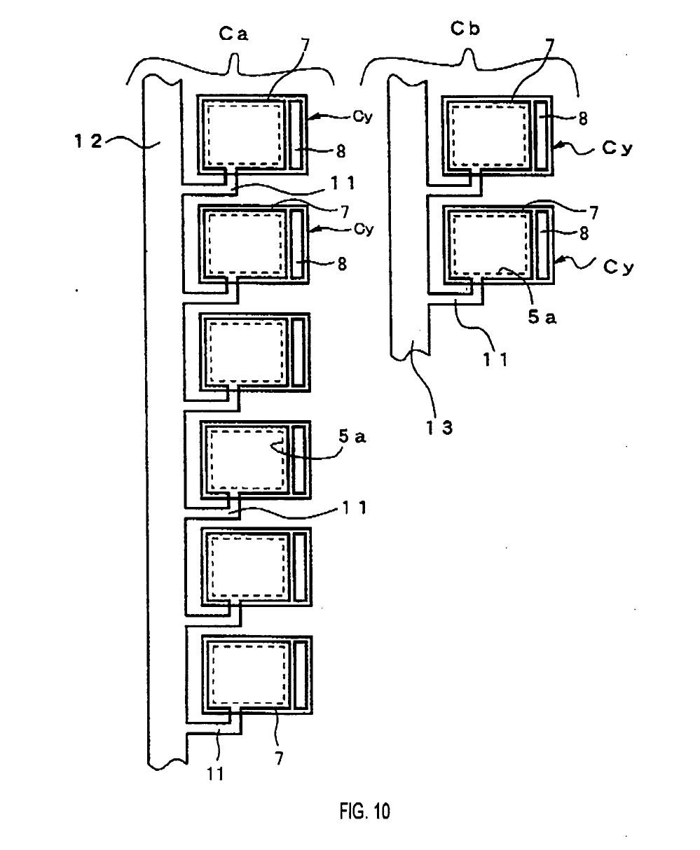

In FIGS. 1 to 8, the same reference numerals are assigned to components equivalent or identical to conventional components shown in the sectional view of FIG. 9, with their description substituted by the description of the aforementioned related art technology.

As shown in the plan view of FIG. 1, the semiconductor device has a pair of capacitive element groups C1 and C2. The left side demarcated by a dashed line is a region of the capacitive element group C1, whereas the right side thereof is a region of the capacitive element group C2. It is to be noted that dummy elements D1 and D2, that will be described later, are provided in a region enclosed by two that the dashed line is split into at the upper portion.

The capacitive element groups C1 and C2 are configured by arranging a number of identical unit capacitive elements Cu. Then, there is disposed the lead-out electrode 8 of the bottom electrode of each of the unit capacitive elements Cu of the capacitive element groups C1 and C2 along the circumference going around the top electrodes 7 as a whole of all the unit capacitive elements Cu.

Therefore, it is unnecessary, as compared with the aforementioned prior-art layout method shown in FIGS. 7A to 7C, to route the lead-out electrode 8 for each of the unit capacitive elements, allowing downsizing of the semiconductor device through area reduction of the capacitive element group and providing improved patterning accuracy as a result of easier patterning. This in turn ensures improved accuracy of capacitance ratio.

In particular, the lead-out electrode 8 is disposed in the shape of a belt so as to surround the top electrodes 7 as a whole of the capacitive element groups C1 and C2. This eliminates the need to dispose the lead-out electrode 8 for each of the capacitive element groups C1 and C2, allowing further reduction in area of the capacitive element groups C1 and C2. Moreover, the lead-out electrode 8 is disposed so as to surround the top electrodes 7 as a whole, facilitating connection of the lead-out electrode 8 with external and other circuitry.

It is to be noted, however, that, as for the lead-out electrode 8 at areas where it intersects with external connection terminals T1 and T2 of the capacitive element groups C1 and C2, the lead-out electrode 8 is cut to provide space. This allows extraction of the external connection terminals T1 and T2 without these terminals overlapping with the lead-out electrode 8. However, all the bottom electrodes of the capacitive element groups C1 and C2 remain connected with each other despite cutting of the lead-out electrode 8 on the surface.

The unit capacitive elements Cu are arranged in grid or array form, with the top electrodes 7 of the unit capacitive elements adjacent to each other joined together in the capacitive element groups C1 and C2. This eliminates the need to form a wiring pattern for drawing out the top electrode 7 outwards for each of the unit capacitive elements Cu, making it possible to mount the unit capacitive elements in large number at high density and thereby ensuring further reduction of the capacitive element groups C1 and C2 in area. This leads to further downsizing of the semiconductor device. Arrangement of the unit capacitive elements in grid form provides improved patterning accuracy as a result of easier patterning, thus ensuring improved accuracy in capacitance ratio.

Further, there are disposed dummy capacitive elements in a vacant region between the capacitive element groups C1 and C2 and the lead-out electrode 8. This prevents generation of steps as a result of no elements existing in the vacant region, thus facilitating patterning and providing improved patterning accuracy. This in turn leads to improved accuracy in capacitance ratio.

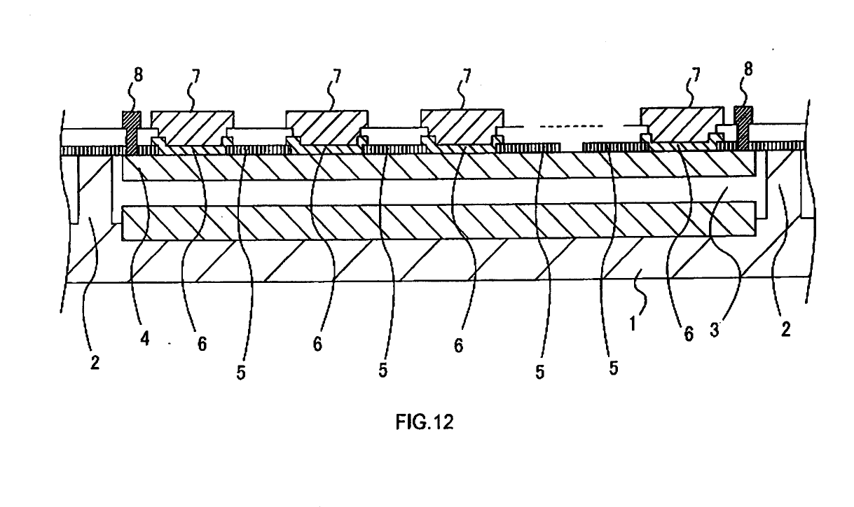

FIG. 12 is a view of the cross-sectional structure of the semiconductor device of FIG. 1 as seen in the X direction after the semiconductor device is cut along the dot-dashed line straight from the front side of the plane of the Figure to the back side.

A bottom electrode 4 is provided as a continuous electrode under a plurality of the top electrodes 7. The plurality of top electrodes 7 are coupled to the bottom electrode 4 via respective dielectric thin films 6 provided for the top electrodes 7. One lead-out electrode 8 is provided and coupled to the bottom electrode 4 at positions adjacent to the top electrodes 7 located at the ends of the Figure without providing a lead-out electrode 8 for each top electrode 7. By this means, the lead-out electrode 8 can be disposed so as to surround the plurality of top electrodes 7 as a whole.

Setting Capacitance Value of Unit Capacitive Element>

A description will be given of setting of the capacitance value (reference capacitance) of the unit capacitive element Cu making up the capacitive element groups C1 and C2 described earlier. Here, it is assumed that the target capacitance value of the capacitive element group C1 is 4.43 pF and that the target capacitance value of the capacitive element group C2 is 3.10 pF. First, the specific capacitance value of the unit capacitive element Cu is set for each of the capacitive element groups C1 and C2 so that the value is as equal to the target capacitance value as possible.

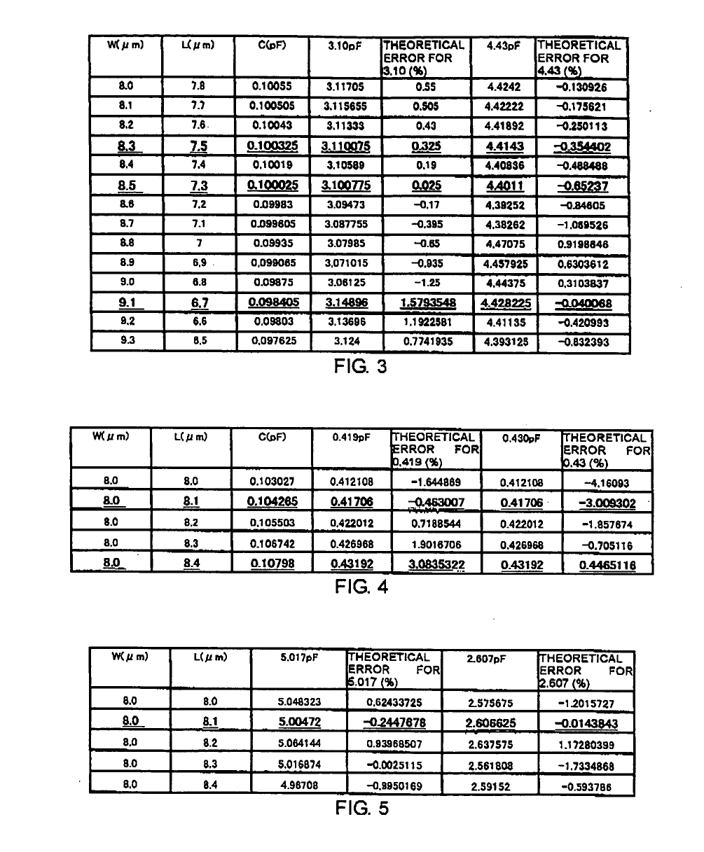

In order to determine the value of the unit capacitive element Cu that achieves the target capacitance value of 4.43 pF of the capacitive element group C1, for instance, error with respect to the target capacitance value was measured using the capacitance values of multiple unit capacitive elements Cu, as shown as a group of data in the table of FIG. 3. For the target capacitance value of 4.43 pF of the capacitive element group C1, we refer to the measured data of the combined capacitance value (second column from right) and the errors with respect to the target capacitance value (rightmost column) in FIG. 3. As a result, we find that the unit capacitive element Cu having a capacitance value of 0.098405 pF (third column from left), with a measured value of 4.428225 pF and an error of −0.040068%, third row from bottom, can minimize the error.

That is, the unit capacitive element Cu with the capacitance value of 0.098405 pF is appropriate for achieving the target capacitance value of 4.43 pF of the capacitive element group C1. The unit capacitive element Cu achieving 0.098405 pF is rectangular in plan view as shown in the first and second columns from left in FIG. 3, with a width (W, leftmost column) of 9.1 μm and a length (L, second column from left) of 6.7 μM.

Similarly, in order to determine the value of the unit capacitive element Cu that achieves the target capacitance value of 3.10 pF of the capacitive element group C2, error with respect to the target capacitance value was measured using the capacitance values of multiple unit capacitive elements Cu, as shown in a group of data in the table of FIG. 3. For the target capacitance value of 3.10 pF of the capacitive element group C2, we refer to the measured data of the combined capacitance value (fourth column from right) and the errors with respect to the target capacitance value (third column from right) in FIG. 3. As a result, we find that the unit capacitive element Cu having a capacitance value of 0.100025 pF (third column from left), with a measured value of 3.100775 pF and an error of −0.025%, sixth row from top, can minimize the error.

That is, the unit capacitive element Cu with the capacitance value of 0.100025 pF is appropriate for achieving the target capacitance value of 3.10 pF of the capacitive element group C2. The unit capacitive element Cu achieving 0.100025 pF is rectangular in plan view as shown in the first and second columns from left in FIG. 3, with a width (W, leftmost column) of 8.5 μm and a length (L, second column from left) of 7.3 μm.

Thus, if the capacitive element groups C1 and C2 are separately and independently integrated into IC chips respectively, it suffices to individually set the optimal unit capacitive elements Cu as described above.

However, to integrate both of the capacitive element groups C1 and C2 into a single semiconductor device as shown in FIG. 1, variations in capacitance value due to variations in manufacture will expand if the capacitance value of the unit capacitive element is set individually for each of the capacitive element groups. Moreover, considering the fact that the capacitance value that can be set in design is finite, selection of the common unit capacitive element Cu for both of the capacitive element groups C1 and C2 facilitates patterning, thus reducing to the extent possible variations in capacitance value due to variations in manufacture. This in turn facilitates manufacturing processes, thus providing improved accuracy of capacitance ratio.

Therefore, referring to the table in FIG. 3 to select the common unit capacitive element Cu for both of the capacitive element groups C1 and C2, it was determined that the unit capacitive element Cu, having a capacitance value of 0.100325 pF (third row from top) with a small error for both of the capacitive element groups C1 and C2, was appropriate. The unit capacitive element Cu achieving 0.100325 pF is rectangular in plan view as shown in the first and second columns from left and on the third row in FIG. 3, with a width (W, leftmost column) of 8.3 μm and a length (L, second column from left) of 7.5 μm.

<Other Embodiments>

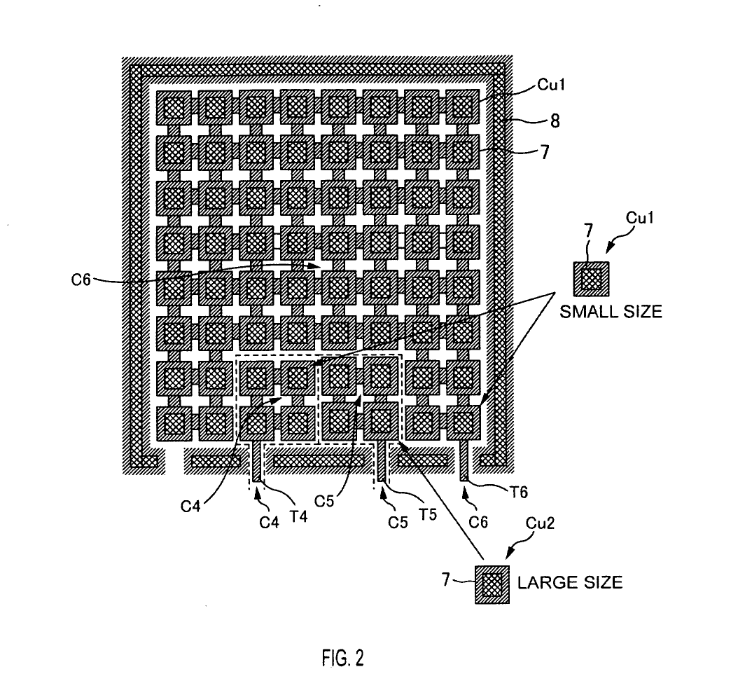

A layout pattern of a semiconductor device according to another embodiment is shown in a plan view of FIG. 2. The following description will focus on differences since there is commonalities/overlap with the semiconductor device described earlier with reference to FIG. 1 including aspects in relation to capacitance value setting for the unit capacitive elements.

The semiconductor device shown in the plan view of FIG. 2 has three capacitive element groups C4, C5 and C6. Of the two regions enclosed by a dashed line at the bottom, the capacitive element group C4 is arranged on the left side, whereas the capacitive element group C5 is arranged on the right side. There is arranged the capacitive element group C6 in the remaining large region.

The capacitive element group C5 uses unit capacitive elements different in size (capacitance) from those of the capacitive element groups C4 and C6. The capacitive element group C5 is configured by arranging identical unit capacitive elements Cu2 that are relatively larger in size. The capacitive element groups C4 and C6 are each configured by arranging the identical unit capacitive elements Cu1 that are relatively smaller in size.

Then, there is disposed the lead-out electrode 8 of the bottom electrodes of the unit capacitive elements Cu of the capacitive element groups C4, C5 and C6 along the circumference going around the top electrodes 7 as a whole of all the unit capacitive elements Cu1 and Cu2 in the capacitive element groups C4, C5 and C6.

As a characteristic ingenuity of layout pattern, if the number of the unit capacitive elements Cu differs between the capacitive element groups C4, C5 and C6, the capacitive element group C6 having a larger number of the unit capacitive elements Cu is disposed so as to surround the capacitive element groups C4 and C5 each having a smaller number of the unit capacitive elements Cu. That is, there are four of the unit capacitive elements Cu each in the capacitive element groups C4 and C5, whereas there are more than ten times as many unit capacitive elements Cu in the capacitive element group C6 as those.

Supposing that, in arranging the capacitive element groups C4, C5 and C6, if the capacitive element group C6 is made rectangular and simply arranged side by side with the capacitive element group C4 that is rectangular in the first place, useless vacant space is generated, inhibiting downsizing as a whole. It is therefore possible to eliminate useless vacant space as shown in FIG. 2 and thereby ensure downsizing as a whole, for example, by employing a layout in which the capacitive element groups C4 and C5, each having a smaller number of the unit capacitive elements Cu, are arranged side by side, with the capacitive element groups C4 and C5 surrounded by the capacitive element group C6 having a larger number of the unit capacitive elements Cu.

Since basic features regarding setting of the capacitance value (reference capacitance) of the unit capacitive element in the present embodiment are the same as in the semiconductor device with the layout pattern of FIG. 1 described earlier, the following description will focus on differences.

First, the unit capacitive element Cu having a specific capacitance value with a smaller error is determined individually for each of the two capacitive element groups C5 and C6. In order to determine the value of the unit capacitive element Cu that achieves a target capacitance value of 0.430 pF of the capacitive element group C5, error with respect to the target capacitance value was measured using the capacitance values of a number of unit capacitive elements Cu, as shown in a group of data in the table of FIG. 4. For the target capacitance value of 0.430 pF of the capacitive element group C5, we refer to the measured data of the combined capacitance value (second column from right) and the errors with respect to the target capacitance value (rightmost column) in FIG. 4. As a result, we find that the unit capacitive element Cu on the bottom row having a capacitance value of 0.10798 pF (third column from left), with a measured value of 0.43192 pF and an error of 0.4465116% (third column from left), can minimize the error.

That is, the unit capacitive element Cu with the capacitance value of 0.10798 pF is appropriate for achieving the target capacitance value of 0.430 pF of the capacitive element group C2. The unit capacitive element Cu achieving 0.10798 pF is rectangular in plan view as shown in the first and second columns from left in FIG. 4, with a width (W, leftmost column) of 8.0 μm and a length (L, second column from left) of 8.4 μm.

In order to determine the value of the unit capacitive element Cu that achieves a target capacitance value of 0.419 pF of the capacitive element group C6, error with the target capacitance value was measured using the capacitance values of a number of unit capacitive elements Cu, as shown in a group of data in the table of FIG. 4. For the target capacitance value of 0.419 pF of the capacitive element group C6, we refer to the measured data of the combined capacitance value (fourth column from left) and the errors with respect to the target capacitance value (fifth column from left) in FIG. 4. As a result, we find that the unit capacitive element Cu on the second row from top having a capacitance value of 0.104265 pF (third column from left), with a measured value of 0.41706 pF and an error of −0.463007%, can minimize the error.

That is, the unit capacitive element Cu with the capacitance value of 0.104265 pF is appropriate for achieving the target capacitance value of 0.419 pF of the capacitive element group C6. The unit capacitive element Cu achieving 0.104265 pF is rectangular in plan view as shown in the first and second columns from left in FIG. 4, with a width (W, leftmost column) of 8.0 μm and a length (L, second column from left) of 8.1 μm.

In determining the value of the unit capacitive element Cu that achieves a target capacitance value of 5.017 pF of the remaining capacitive element group C4 in the semiconductor device shown in FIG. 2, a unit capacitive element, equivalent to that making up the capacitive element group C5 or C6, is employed. This reduces variations in capacitance value due to variations in manufacture, as compared with setting the capacitance value of the unit capacitive element to a different value for each of the capacitive element groups. Error with respect to the target capacitance value was measured using the capacitance values of a number of unit capacitive elements Cu including those making up the capacitive element groups C5 and C6 (8.0 μm*8.4 μm and 8.0 μm*8.1 μm), as shown in a group of data in the table of FIG. 5. For the target capacitance value of 5.017 pF of the capacitive element group C4, we refer to the measured data of the combined capacitance value (third column from left) and the errors with respect to the target capacitance value (fourth column from left) in FIG. 5. As a result, we find that the unit capacitive element Cu of 8.0 μm*8.1 μm in size on the second row from top, i.e., the same element as that making up the capacitive element group C6 offers an error of −0.2447678%, smaller than −0.9950169% offered by the unit capacitive element Cu of 8.0 μm*8.4 μm in size on the bottom row, the same element as that making up the capacitive element group C5. As a unit capacitive element Cu making up the capacitive element group C4, therefore, it is appropriate to employ the same unit capacitive element Cu as that making up the capacitive element group C6.

It is to be noted that even when a capacitance C3 (2.607 pF), used in the voltage dividing circuits in FIGS. 7A to 7C that will be described later, is configured with capacitive element groups, it is appropriate to employ the unit capacitive element Cu of 8.0 μm*8.1 μm in size making up the capacitive element group C6 with a smaller error as compared with that making up the capacitive element group C5 (8.0 μm*8.4 μm), as is done in the case of the capacitive element group C4, as shown in the group of data in the table of FIG. 5. That is, if, in configuring the capacitance C3 with capacitive element groups, the capacitance C3 is patterned in the same manufacturing process as with the other capacitive element groups C4 to C6 in the voltage dividing circuits of FIGS. 7A to 7C, it is possible to reduce variations in capacitance value due to variations in manufacture by employing the same unit capacitive element as in the other capacitive element groups C4 and C6.

<Example of Application to Circuitry for Specific Purpose>

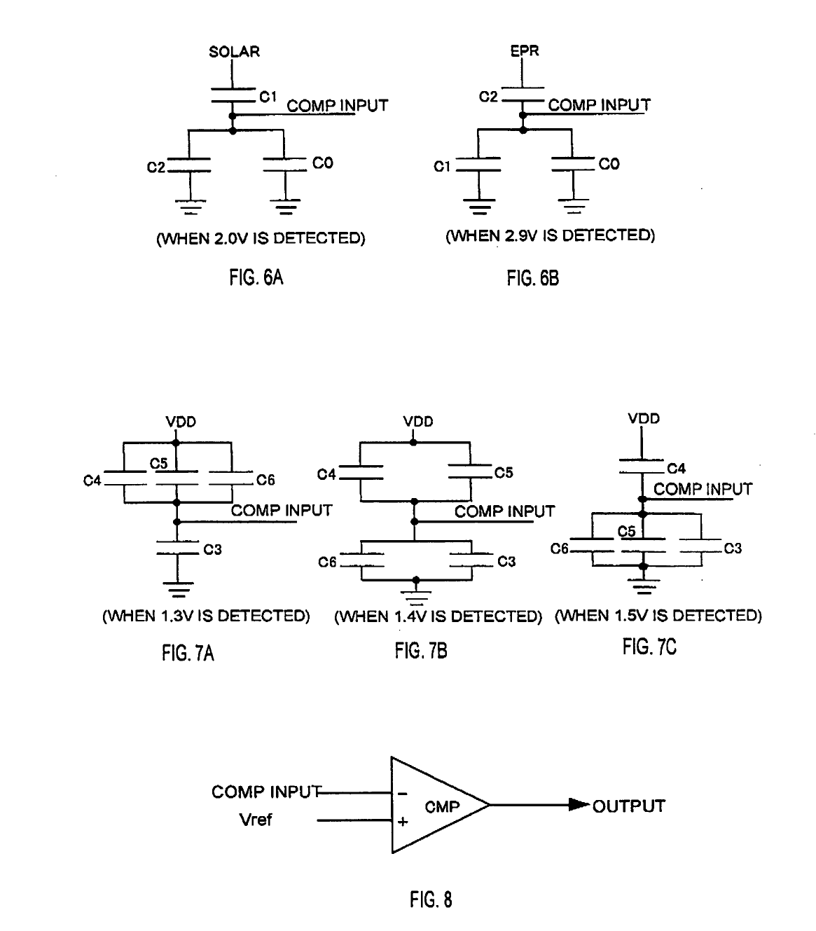

The semiconductor device described with reference to FIG. 1 is used, for example, in voltage dividing circuits capable of ensuring accuracy to 0.1 V shown in FIGS. 6A and 6B. The voltage dividing circuit of FIG. 6A detects 2.0V, a set voltage, with a SOLAR terminal, whereas the one of FIG. 6B detects 2.9V, a set voltage, with an EPR terminal. A capacitance C1 used in the voltage dividing circuits is constituted by the capacitive element group C1 in the semiconductor device in FIG. 1. On the other hand, a capacitance C2 is constituted by the capacitive element group C2 in the semiconductor device in FIG. 1.

The voltage dividing circuit of FIG. 6A has the capacitance C1 connected in series with a parallel circuit of capacitances C0 and C2, each of which is connected to ground at one end. The connection point between the parallel circuit and the capacitance C1, serving as a COMP input terminal, is connected to circuitry at the succeeding stage.

On the other hand, the voltage dividing circuit of FIG. 6B has the capacitance C2 connected in series with a parallel circuit of the capacitances C0 and C1, each of which is connected to ground at one end. The connection point between the parallel circuit and the capacitance C2, serving as the COMP input terminal, is connected to circuitry at the succeeding stage.

A given capacitance ratio of the capacitances C0, C1 and C2 is set for both voltage dividing circuits. As a result, when voltages applied to the input terminals SOLAR and EPR are set voltages of 2.0V and 2.9V as respective references, a voltage with 0.9V as a reference—a common voltage—is obtained from the COMP input terminal, a connection point of the three capacitances. That is, if voltages applied to the input terminals SOLAR and EPR change upward or downward respectively relative to the set voltages 2.0V and 2.9V as the center, the voltage of the COMP input terminal changes upward or downward relative to the common voltage 0.9V as the center.

These voltage dividing circuits can be employed as part of a voltage detection circuit in a measuring instrument such as electronic calipers. That is, a comparator CMP as shown in FIG. 8 can be used as a circuit connected at the succeeding stage to these voltage dividing circuits. That is, the COMP input terminal of each voltage dividing circuit is connected to the inverting input of the comparator CMP. A reference voltage Vref of 0.9V is applied as a comparison reference to the non-inverting input terminal of the comparator CMP. This configuration provides a positive or negative output from the common comparator CMP as voltages applied to the input terminals SOLAR and EPR of the voltage dividing circuits change relative to the respective set voltages 2.0V and 2.9V as the center.

Next, the semiconductor device having the layout pattern as described with reference to FIG. 2 is used, for example, in voltage dividing circuits capable of ensuring accuracy to 0.1 V shown in FIGS. 7A to 7C. The voltage dividing circuit of FIG. 7A detects a set voltage of 1.3V with a VDD terminal, and the voltage dividing circuit of FIG. 7B detects a set voltage of 1.4V with the VDD terminal, whereas the voltage dividing circuit of FIG. 7C detects a set voltage of 1.5V with the VDD terminal. A capacitance C4 used in the individual voltage dividing circuits is constituted by the capacitive element group C4 in the semiconductor device of FIG. 2. On the other hand, a capacitance C5 used in the individual voltage dividing circuits is constituted by the capacitive element group C5 in the semiconductor device of FIG. 2. Further, a capacitance C6 used in the individual voltage dividing circuits is constituted by the capacitive element group C6 in the semiconductor device of FIG. 2.

In the voltage dividing circuit of FIG. 7A, a parallel circuit of the capacitances C4, C5 and C6 is connected in series with a capacitance C3 that is grounded at one end. The connection point between the parallel circuit and the capacitance C3 serves as the COMP input terminal and is connected to a circuit at the succeeding stage.

In the voltage dividing circuit of FIG. 7B, a parallel circuit of the capacitances C4 and C5 is connected in series with a parallel circuit of the capacitances C6 and C3, each of which is grounded at one end. The connection point between the parallel circuits serves as the COMP input terminal and is connected to a circuit at the succeeding stage.

Further, in the voltage dividing circuit of FIG. 7C, the capacitance C4 is connected in series with a parallel circuit of the capacitances C6, C5 and C3, each of which is grounded at one end. The connection point between the parallel circuit and the capacitance C4 serves as the COMP input terminal and is connected to a circuit at the succeeding stage.

For each of the three voltage dividing circuits, a given capacitance ratio of the capacitances C3 to C6 is set. As a result, a voltage with the common voltage of 0.9V as a reference is obtained from the COMP terminal in response to the set voltages of 1.3V, 1.4V and 1.5V as respective references, applied to the input terminals VDD. That is, if voltages applied to the input terminals VDD change upward or downward respectively relative to the set voltages of 1.3V, 1.4V and 1.5V as the center, the voltage of the COMP input terminal changes upward or downward relative to the common voltage 0.9V as the center.

These voltage dividing circuits can be employed as part of a voltage detection circuit in a measuring instrument such as electronic calipers. That is, the comparator CMP as shown in FIG. 8 can be used as a circuit connected at the succeeding stage to these voltage dividing circuits. That is, the COMP input terminal of each of the voltage dividing circuit is connected to the inverting input of the comparator CMP. The reference voltage Vref of 0.9V is applied as a comparison reference to the non-inverting input terminal of the comparator CMP. This configuration provides a positive or negative output from the common comparator CMP as voltages applied to the input terminals VDD of the voltage dividing circuits change relative to the respective set voltages of 1.3V, 1.4V and 1.5V as the center.

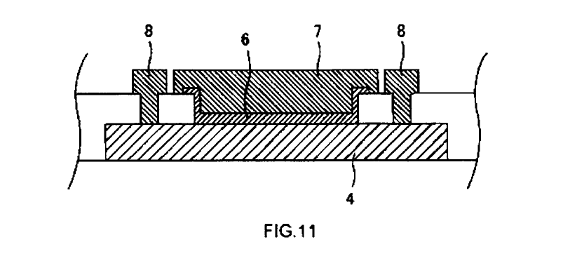

While a cross-sectional structure shown in FIG. 9 is taken as an example of the cross-sectional structure of the unit capacitive element, various forms of cross-sectional structures can be applied to the present invention. The cross-sectional structure shown in FIG. 11 is also preferred as an embodiment of the present invention. That is, the lead-out electrode 8 of the bottom electrode is arranged adjacent to the circumference of the top electrode 7 in a cross-sectional structure of a unit capacitive element as shown in FIG. 11.

It is possible to set the unit capacitive elements capable of minimizing the error with respect to the target capacitance value to the extent possible for the capacitive element groups, thus allowing the highly accurate capacitive element groups to be obtained. This allows downsizing of the semiconductor device through area reduction of the capacitive element groups while at the same time ensuring high accuracy in the capacitive element groups, and provides improved patterning accuracy as a result of easier patterning. This in turn ensures improved accuracy of capacitance ratio.

If there is a vacant region free of the unit capacitive elements between the top electrodes as a whole of the capacitive element group and the lead-out electrode, dummy elements can be disposed in the vacant region. This prevents generation of steps as a result of no elements existing in the vacant region, thus facilitating patterning and providing improved patterning accuracy. This in turn leads to improved accuracy in capacitance ratio.

Further, if the number of unit capacitive elements differs between the capacitive element groups, the capacitive element group having a larger number of unit capacitive elements can be disposed so as to surround the capacitive element group having a smaller number of unit capacitive elements. This eliminates useless space to the extent possible, thus allowing downsizing as a whole.

While illustrative and presently preferred embodiments of the present invention have been described in detail herein, it is to be understood that the inventive concepts may be otherwise variously embodied and employed and that the appended claims are intended to be construed to include such variations except insofar as limited by the conventional art.

1. A semiconductor device comprising a capacitive element group that has a plurality of unit capacitive elements, wherein
the unit capacitive element has a capacitance value that is set so as to reduce an error between a target capacitance value of the capacitive element group and a combined capacitance value of the plurality of unit capacitive elements making up the capacitive element group.

2. The semiconductor device according to claim 1, wherein a plurality of the capacitive element groups are formed in the semiconductor device.

3. The semiconductor device according to claim 2, wherein the plurality of capacitive element groups use in common the unit capacitive element having the capacitance value which is set so as to make the error smaller.

4. The semiconductor device according to claim 2, wherein some of the capacitive element groups each include a unit capacitive element having a capacitance value specific thereto which is set so as to make the error smaller, and wherein a unit capacitive element making up the capacitive element groups other than the some of the capacitive element groups is equivalent to any one of the unit capacitive elements making up the some of the capacitive element groups.

5. The semiconductor device according to claim 1, wherein at least one lead-out electrode for bottom electrodes of the unit capacitive elements of the capacitive element group is disposed along a circumference around top electrodes as a whole of the capacitive element group.

6. The semiconductor device according to claim 5, wherein if there is a vacant region free of the unit capacitive elements between the top electrodes as a whole of the capacitive element group and the lead-out electrode, dummy elements are disposed in the vacant region.

7. The semiconductor device according to claim 2, wherein if the number of unit capacitive elements differs between the capacitive element groups, a capacitive element group having a larger number of unit capacitive elements is disposed so as to surround a capacitive element group having a smaller number of unit capacitive elements.

8. The semiconductor device according to claim 5, wherein one lead-out electrode is formed by integrating the at least one lead-out electrode of the unit capacitive elements.

9. The semiconductor device according to claim 1, wherein the unit capacitive elements are arranged in grid form, and wherein the top electrodes of the unit capacitive elements adjacent to each other are joined together in the capacitive element group.

10. The semiconductor device according to claim 1, which is used for a voltage dividing circuit comprising, as a constituent element, the capacitive element group.
